(19) United States
(12) Patent Application Publication
(10) Pub. No.: US 2009/0255583 A1
(43) Pub. Date: Oct. 15, 2009

(54) ALUMINUM PASTES AND USE THEREOF IN THE PRODUCTION OF SILICON SOLAR CELLS

(75) Inventors: Richard John Sheffield Young, Somerset (GB); Alistair Graeme Prince, Bristol (GB)

Correspondence Address: E I DU PONT DE NEMOURS AND COMPANY;LEGAL PATENT RECORDS CENTER, BARLEY MILL PLAZA 25/1122B, 4417 LANCASTER PIKE, WILMINGTON, DE, 19805, US

(73) Assignee: E.I. DU PONT DE NEMOURS AND COMPANY, Wilmington, DE (US)

(21) Appl. No.: 12/420,911

(22) Filed: Apr. 9, 2009

Related U.S. Application Data
(60) Provisional application No. 61/044,984, filed on Apr. 15, 2008.

(51) Int. Cl. H01L 31/00; C09K 17/40; C08K 3/08; H01L 21/283

(52) U.S. Cl. 136/261; 106/287.17; 524/441; 438/57; 257/E21.159

(57) ABSTRACT

Aluminum pastes comprising particulate aluminum, a tin-organic component and an organic vehicle and their use in forming p-type aluminum back electrodes of silicon solar cells.

### FIELD OF THE INVENTION

The present invention is directed to aluminum pastes, and their use in the production of silicon solar cells, i.e., in the production of aluminum back electrodes of silicon solar cells and the respective silicon solar cells.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate hole-electron pairs in that body. The potential difference that exists at a p-n junction, causes holes and electrons to move across the junction in opposite directions and thereby give rise to flow of an electric current that is capable of delivering power to an external circuit. Most solar cells are in the form of a silicon wafer that has been metallized, i.e., provided with metal contacts which are electrically conductive.

During the formation of a silicon solar cell, an aluminum paste is generally screen printed and dried on the back-side of the silicon wafer. The wafer is then fired at a temperature above the melting point of aluminum to form an aluminum-silicon melt, subsequently, during the cooling phase, a epitaxially grown layer of silicon is formed that is doped with aluminum. This layer is generally called the back surface field (BSF) layer, and helps to improve the energy conversion efficiency of the solar cell.

Most electric power-generating solar cells currently used are silicon solar cells. Process flow in mass production is generally aimed at achieving maximum simplification and minimizing manufacturing costs. Electrodes in particular are made by using a method such as screen printing from a metal paste.

An example of this method of production is described below in conjunction with FIG. 1. FIG. 1A shows a p-type silicon substrate, 10.

In FIG. 1B, an n-type diffusion layer, 20, of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer, 20, is formed over the entire surface of the silicon substrate, 10. The p-n junction is formed where the concentration of the p-type dopant equals the concentration of the n-type dopant; conventional cells that have the p-n junction close to the sun side, have a junction depth between 0.05 and 0.5 μm.

After formation of this diffusion layer excess surface glass is removed from the rest of the surfaces by etching by an acid such as hydrofluoric acid.

Next, an antireflective coating (ARC), 30, is formed on the n-type diffusion layer, 20, to a thickness of between 0.05 and 0.1 μm in the manner shown in FIG. 1D by a process, such as, for example, plasma chemical vapor deposition (CVD).

As shown in FIG. 1E, a front-side silver paste (front electrode-forming silver paste), 500, for the front electrode is screen printed and then dried over the antireflective coating, 30. In addition, a back-side silver or silver/aluminum paste, 70, and an aluminum paste, 60, are then screen printed (or some other application method) and successively dried on the back-side of the substrate. Normally, the back-side silver or silver/aluminum paste is screen printed onto the silicon first as two parallel strips (busbars) or as rectangles (tabs) ready for soldering interconnection strings (presoldered copper ribbons), the aluminum paste is then printed in the bare areas with a slight overlap over the back-side silver or silver/aluminum. In some cases, the silver or silver/aluminum paste is printed after the aluminum paste has been printed. Firing is then typically carried out in a belt furnace for a period of 1 to 5 minutes with the wafer reaching a peak temperature in the range of 700 to 900° C. The front and back electrodes can be fired sequentially or cofired.

Consequently, as shown in FIG. 1F, molten aluminum from the paste dissolves the silicon during the firing process and then on cooling forms a eutectic layer that epitaxially grows from the silicon base, 10, forming a p+ layer, 40, containing a high concentration of aluminum dopant. This layer is generally called the back surface field (BSF) layer, and helps to improve the energy conversion efficiency of the solar cell. A thin layer of aluminum is generally present at the surface of this epitaxial layer.

The aluminum paste is transformed by firing from a dried state, 60, to an aluminum back electrode, 61. The back-side silver or silver/aluminum paste, 70, is fired at the same time, becoming a silver or silver/aluminum back electrode, 71. During firing, the boundary between the back-side aluminum and the back-side silver or silver/aluminum assumes an alloy state, and is connected electrically as well. The aluminum electrode accounts for most areas of the back electrode, owing in part to the need to form a p+ layer, 40. A silver or silver/aluminum back electrode is formed over portions of the back-side (often as 2 to 6 mm wide busbars) as an electrode for interconnecting solar cells by means of pre-soldered copper ribbon or the like. In addition, the front-side silver paste, 500, sinters and penetrates through the antireflective coating, 30, during firing, and is thereby able to electrically contact the n-type layer, 20. This type of process is generally called “firing through”. This fired through state is apparent in layer 501 of FIG. 1F.

Silicon solar cells made from silicon wafers and having an aluminum back electrode are silicon/aluminum bimetallic strips and may exhibit a so-called bowing behavior. Bowing is undesirable in that it might lead to cracking and breaking of the solar cells. Bowing also causes problems with regard to processing of the silicon wafers. During processing the silicon wafers are generally lifted up making use of automated handling equipment using suction pads which may not work reliably in case of excessive bowing. Bowing requirements within the photovoltaic industry are typically <1.5 mm deflection of the solar cells. Overcoming the bowing phenomenon is a challenge especially with a view to silicon solar cells made from large and/or thin silicon wafers, for example, silicon wafers having a thickness below 180 μm, in particular, in the range of 120 to below 180 μm and an area in the range of above 250 to 400 cm².

A further problem associated with the aluminum paste is dusting and transfer of free aluminum or alumina dust to other metallic surfaces, thereby reducing the solderability and adhesion of ribbons tabbed to said surface. This is particularly relevant when the firing process is performed with stacked solar cells.

US-A-2007/0079868 discloses aluminum thick film compositions which can be used in forming aluminum back electrodes of silicon solar cells. Apart from aluminum powder, an organic medium as vehicle and glass frit as an optional constituent the aluminum thick film compositions comprise amorphous silicon dioxide as an essential constituent. The amorphous silicon dioxide serves in particular to reduce the bowing behavior of the silicon solar cells.

It has now been found that aluminum thick film compositions having a similar or even better performance can be obtained when the aluminum thick film compositions disclosed in US-A-2007/0079868 comprise certain tin-organic components instead of or in addition to the amorphous silicon dioxide.

### SUMMARY OF THE INVENTION

The present invention relates to aluminum pastes (aluminum thick film compositions) for use in forming p-type aluminum back electrodes of silicon solar cells. It further relates to the process of forming and use of the aluminum pastes in the production of silicon solar cells and the silicon solar cells themselves.

The present invention is directed to aluminum pastes comprising: particulate aluminum, a tin-organic component, an organic vehicle and as optional components: a zinc-organic component, one or more glass frit compositions and amorphous silicon dioxide.

The present invention is further directed to a process of forming a silicon solar cell and the silicon solar cell itself which utilizes a silicon wafer having a p-type and an n-type region, and a p-n junction, which comprises applying, in particular, screen-printing an aluminum paste of the present invention on the back-side of the silicon wafer, and firing the printed surface, whereby the wafer reaches a peak temperature in the range of 700 to 900° C.

### BRIEF DESCRIPTION OF THE FIGURES

FIG. 1 is a process flow diagram illustrating exemplary the fabrication of a silicon solar cell.

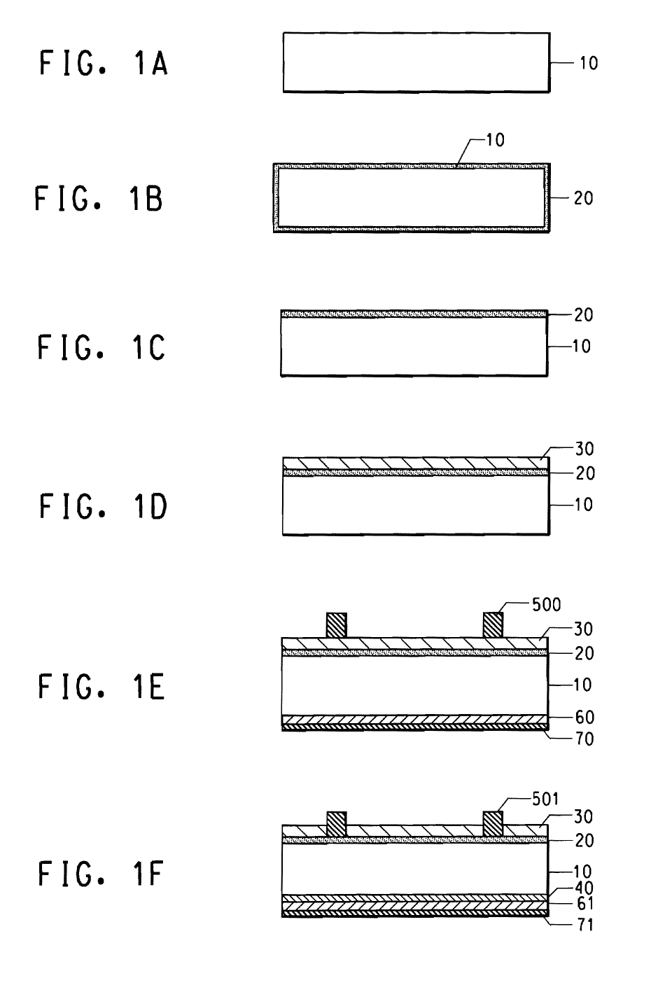

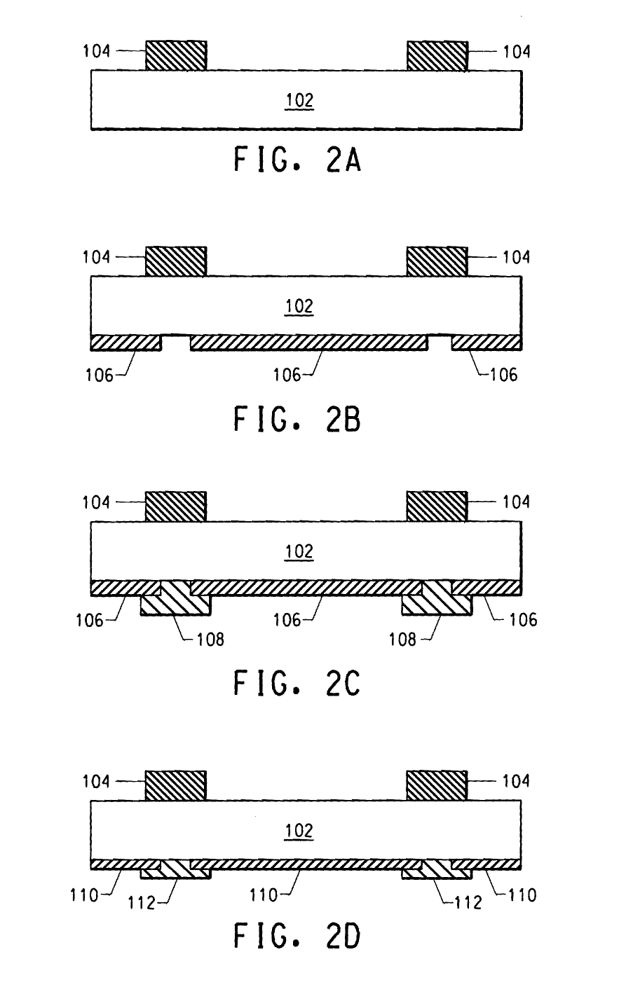

Reference numerals shown in FIG. 1 are explained below.

10: p-type silicon wafer

20: n-type diffusion layer

30: antireflective coating, for example, SiNx, TiOx, SiOx

40: p+ layer (back surface field, BSF)

60: aluminum paste formed on back-side

61: aluminum back electrode (obtained by firing back-side aluminum paste)

70: silver or silver/aluminum paste formed on back-side

71: silver or silver/aluminum back electrode (obtained by firing back-side silver or silver/aluminum paste)

500: silver paste formed on front-side

501: silver front electrode (obtained by firing front-side silver paste)

FIGS. 2 A-D explain the manufacturing process for manufacturing a silicon solar cell using an electroconductive aluminum paste of the present invention. Reference numerals shown in FIG. 2 are explained below.

102 silicon substrate (silicon wafer)

104 light-receiving surface side electrode

106 paste composition for a first electrode

108 electroconductive paste for a second electrode

110 first electrode

112 second electrode

### DETAILED DESCRIPTION OF THE INVENTION

The aluminum dusting problem described above can be minimized or even be eliminated with the novel aluminum thick film compositions. Use of said novel aluminum thick film compositions in the production of aluminum back electrodes of silicon solar cells results in silicon solar cells exhibiting not only low bowing behavior and good electrical performance but also reduced or even no tendency of adhesion loss between the aluminum back electrode and the silicon wafer substrate. Good adhesion between the aluminum back electrode and the silicon wafer substrate leads to a prolonged durability or service life of the silicon solar cells.

The aluminum pastes of the present invention comprise particulate aluminum, a tin-organic component and an organic vehicle (organic medium). In different embodiments, they comprise also one or more glass frits, a zinc-organic component or one or more glass frits and a zinc-organic component.

The particulate aluminum may be comprised of aluminum or an aluminum alloy with one or more other metals like, for example, zinc, tin, silver and magnesium. In case of aluminum alloys the aluminum content is, for example, 99.7 to below 100 wt. %. The particulate aluminum may comprise aluminum particles in various shapes, for example, aluminum flakes, spherical-shaped aluminum powder, nodular-shaped (irregular-shaped) aluminum powder or any combinations thereof. Particulate aluminum, in an embodiment, is in the form of aluminum powder. The aluminum powder exhibits an average particle size (mean particle diameter) determined by means of laser scattering of, for example, 4 to 10 μm. The particulate aluminum may be present in the aluminum pastes of the present invention in a proportion of 50 to 80 wt. %, or, in an embodiment, 70 to 75 wt. %, based on total aluminum paste composition.

All statements made in the present description and the claims in relation to average particle sizes relate to average particle sizes of the relevant materials as are present in the aluminum paste composition.

The particulate aluminum present in the aluminum pastes may be accompanied by other particulate metal(s) such as, for example, silver or silver alloy powders. The proportion of such other particulate metal(s) is, for example, 0 to 10 wt. %, based on the total of particulate aluminum plus particulate metal(s).

The aluminum pastes of the present invention comprise a tin-organic component; in an embodiment, the tin-organic component may be a liquid tin-organic component. The term “tin-organic component” herein refers to solid tin-organic compounds and liquid tin-organic components. The term “liquid tin-organic component” means a solution of one or more tin-organic compounds in organic solvent(s) or, in an embodiment, one or more liquid tin-organic compounds themselves.

In the context of the present invention the term “tin-organic compound” includes such tin compounds that comprise at least one organic moiety in the molecule. The tin-organic compounds are stable or essentially stable, for example, in the presence of atmospheric oxygen or air humidity, under the conditions prevailing during preparation, storage and application of the aluminum pastes of the present invention. The same is true under the application conditions, in particular, under those conditions prevailing during screen printing of the aluminum pastes onto the back-side of the silicon wafers. However, during firing of the aluminum pastes the organic portion of the tin-organic compounds will or will essentially be removed, for example, burned and/or carbonized. The tin-organic compounds as such have a tin content, in an embodiment, in the range of 25 to 35 wt. %. The tin-organic compounds may comprise covalent tin-organic compounds; in particular they comprise tin-organic salt compounds. Examples of suitable tin-organic salt compounds include in particular tin resinates (tin salts of acidic resins, in particular, resins with carboxyl groups) and tin carboxylates (tin carboxylic acid salts). In an embodiment, the tin-organic compound may be tin(II)octoate or, more precisely, tin(II) 2-ethylhexanoate, which is liquid at room temperature. Tin(II) 2-ethylhexanoate is commercially available, for example, from Rohm and Haas. In case of liquid tin-organic compounds such as tin(II) 2-ethylhexanoate, the undissolved liquid tin-organic compound(s) itself/themselves may be used when preparing the aluminum pastes of the present invention; the tin(II) 2-ethylhexanoate may form the liquid tin-organic component.

The tin-organic component may be present in the aluminum pastes of the present invention in a proportion corresponding to a tin contribution of 0.01 to 0.5 wt. %, or, in an embodiment, 0.1 to 0.15 wt. %, based on total aluminum paste composition. In case of tin(II) 2-ethylhexanoate its proportion in the aluminum pastes may be in the range of 0.1 to 1 wt. %, or, in an embodiment, 0.3 to 0.5 wt. %, based on total aluminum paste composition.

The aluminum pastes of the present invention may further comprise a zinc-organic component; in an embodiment, the zinc-organic component may be a liquid zinc-organic component. The term “zinc-organic component” herein refers to solid zinc-organic compounds and liquid zinc-organic components. The term “liquid zinc-organic component” means a solution of one or more zinc-organic compounds in organic solvent(s) or, in an embodiment, one or more liquid zinc-organic compounds themselves.

The zinc-organic component of the aluminum pastes of the present invention, in a non-limiting embodiment, is substantially free of unoxidized zinc metal; in a further embodiment, the zinc-organic component may be greater than 90% free of unoxidized zinc metal; in a further embodiment, the zinc-organic component may be greater than 95%, 97%, or 99% free of unoxidized zinc metal. In an embodiment, the zinc-organic component may be free of unoxidized zinc metal.

In the context of the present invention the term “zinc-organic compound” includes such zinc compounds that comprise at least one organic moiety in the molecule. The zinc-organic compounds are stable or essentially stable, for example, in the presence of atmospheric oxygen or air humidity, under the conditions prevailing during preparation, storage and application of the aluminum pastes of the present invention. The same is true under the application conditions, in particular, under those conditions prevailing during screen printing of the aluminum pastes onto the back-side of the silicon wafers. However, during firing of the aluminum pastes the organic portion of the zinc-organic compounds will or will essentially be removed, for example, burned and/or carbonized. The zinc-organic compounds as such have a zinc content, in an embodiment, in the range of 15 to 30 wt. %. The zinc-organic compounds may comprise covalent zinc-organic compounds; in particular they comprise zinc-organic salt compounds. Examples of suitable zinc-organic salt compounds include in particular zinc resinates (zinc salts of acidic resins, in particular, resins with carboxyl groups) and zinc carboxylates (zinc carboxylic acid salts). In an embodiment, the zinc-organic compound may be zinc neodecanoate, which is liquid at room temperature. Zinc neodecanoate is commercially available, for example, from Shepherd Chemical Company. In case of liquid zinc-organic compounds such as zinc neodecanoate, the undissolved liquid zinc-organic compound(s) itself/themselves may be used when preparing the aluminum pastes of the present invention; the zinc neodecanoate may form the liquid zinc-organic component.

In case of the aluminum pastes comprising a zinc-organic component the latter may be present in the aluminum pastes in a proportion corresponding to a zinc contribution of 0.05 to 0.6 wt. %, or, in an embodiment, 0.1 to 0.25 wt. %, based on total aluminum paste composition. In case of zinc neodecanoate its proportion in the aluminum pastes may be in the range of 0.5 to 3.0 wt. %, or, in an embodiment, 0.5 to 1.2 wt. %, based on total aluminum paste composition.

In an embodiment, the aluminum pastes of the present invention comprise at least one glass frit composition as an inorganic binder. The glass frit compositions may contain PbO; in an embodiment, the glass frit compositions may be leadfree. The glass frit compositions may comprise those which upon firing undergo recrystallization or phase separation and liberate a frit with a separated phase that has a lower softening point than the original softening point.

The (original) softening point (glass transition temperature, determined by differential thermal analysis DTA at a heating rate of 10 K/min) of the glass frit compositions may be in the range of 325 to 600° C.

The glass frits exhibit average particle sizes (mean particle diameters) determined by means of laser scattering of, for example, 2 to 20 μm. In case of the aluminum pastes comprising glass-frit(s) the glass frit(s) content may be 0.01 to 5 wt. %, or, in an embodiment, 0.1 to 2 wt. %, or, in a further embodiment, 0.2 to 1.25 wt. %, based on total aluminum paste composition.

Some of the glass frits useful in the aluminum pastes are conventional in the art. Some examples include borosilicate and aluminosilicate glasses. Examples further include combinations of oxides, such as: B₂O₃, SiO₂, Al₂O₃, CdO, CaO, BaO, ZnO, Na₂O, Li₂O, PbO, and ZrO₂ which may be used independently or in combination to form glass binders.

The conventional glass frits may be the borosilicate frits, such as lead borosilicate frit, bismuth, cadmium, barium, calcium, or other alkaline earth borosilicate frits. The preparation of such glass frits is well known and consists, for example, in melting together the constituents of the glass in the form of the oxides of the constituents and pouring such molten composition into water to form the frit. The batch ingredients may, of course, be any compounds that will yield the desired oxides under the usual conditions of frit production. For example, boric oxide will be obtained from boric acid, silicon dioxide will be produced from flint, barium oxide will be produced from barium carbonate, etc.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The glasses are prepared by conventional glassmaking techniques, by mixing the desired components in the desired proportions and heating the mixture to form a melt. As is well known in the art, heating may be conducted to a peak temperature and for a time such that the melt becomes entirely liquid and homogeneous.

The aluminum pastes of the present invention may comprise amorphous silicon dioxide. The amorphous silicon dioxide is a finely divided powder. In an embodiment, it may have an average particle size (mean particle diameter) determined by means of laser scattering of, for example, 5 to 100 nm. Particularly it comprises synthetically produced silica, for example, pyrogenic silica or silica produced by precipitation. Such silicas are supplied by various producers in a wide variety of types.

In case the aluminum pastes of the present invention comprise amorphous silicon dioxide, the latter may be present in the aluminum pastes in a proportion of, for example, above 0 to 0.5 wt. %, for example, 0.01 to 0.5 wt. %, or, in an embodiment, 0.05 to 0.1 wt. %, based on total aluminum paste composition.

The aluminum pastes of the present invention comprise an organic vehicle. A wide variety of inert viscous materials can be used as organic vehicle. The organic vehicle may be one in which the particulate constituents (particulate aluminum, amorphous silicon dioxide if any, glass frit if any) are dispersible with an adequate degree of stability. The properties, in particular, the rheological properties, of the organic vehicle may be such that they lend good application properties to the aluminum paste composition, including: stable dispersion of insoluble solids, appropriate viscosity and thixotropy for application, in particular, for screen printing, appropriate wettability of the silicon wafer substrate and the paste solids, a good drying rate, and good firing properties. The organic vehicle used in the aluminum pastes of the present invention may be a nonaqueous inert liquid. The organic vehicle may be an organic solvent or an organic solvent mixture; in an embodiment, the organic vehicle may be a solution of organic polymer(s) in organic solvent(s). In an embodiment, the polymer used for this purpose may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the aluminum paste on the backside of the silicon wafer can be included in the organic vehicle. Various combinations of these and other solvents may be formulated to obtain the viscosity and volatility requirements desired.

The organic solvent content in the aluminum pastes of the present invention may be in the range of 5 to 25 wt. %, or, in an embodiment, 10 to 20 wt. %, based on total aluminum paste composition. The number of 5 to 25 wt. % includes a possible organic solvent contribution from a liquid tin-organic component and an optional liquid zinc-organic component.

The organic polymer(s) may be present in the organic vehicle in a proportion in the range of 0 to 20 wt. %, or, in an embodiment, 5 to 10 wt. %, based on total aluminum paste composition.

The aluminum pastes of the present invention may comprise one or more organic additives, for example, surfactants, thickeners, rheology modifiers and stabilizers. The organic additive(s) may be part of the organic vehicle. However, it is also possible to add the organic additive(s) separately when preparing the aluminum pastes. The organic additive(s) may be present in the aluminum pastes of the present invention in a total proportion of, for example, 0 to 10 wt. %, based on total aluminum paste composition.

The organic vehicle content in the aluminum pastes of the present invention may be dependent on the method of applying the paste and the kind of organic vehicle used, and it can vary. In an embodiment it may be from 20 to 45 wt. %, or, in an embodiment, it may be in the range of 22 to 35 wt. %, based on total aluminum paste composition. The number of 20 to 45 wt. % includes organic solvent(s), possible organic polymer(s) and possible organic additive(s).

In an embodiment, aluminum pastes of the present invention comprise
70 to 75 wt. % of particulate aluminum,
tin-organic component(s) in a proportion corresponding to a tin contribution of 0.1 to 0.15 wt. %, in particular, 0.3 to 0.5 wt. % tin(II) 2-ethyl hexanoate,
0.2 to 1.25 wt. % of one or more glass frits,
0 to 0.5 wt. % of amorphous silicon dioxide,
10 to 20 wt. % of one or more organic solvents,
5 to 10 wt. % of one or more organic polymers, and
0 to 5 wt. % of one or more organic additives.

In an embodiment, aluminum pastes of the present invention comprise
70 to 75 wt. % of particulate aluminum,
tin-organic component(s) in a proportion corresponding to a tin contribution of 0.1 to 0.15 wt. %, in particular, 0.3 to 0.5 wt. % tin(II) 2-ethyl hexanoate,
zinc-organic component(s) in a proportion corresponding to a zinc contribution of 0.1 to 0.25 wt. %, in particular, 0.5 to 1.2 wt. % zinc neodecanoate,
0.2 to 1.25 wt. % of one or more glass frits,
0 to 0.5 wt. % of amorphous silicon dioxide,
10 to 20 wt. % of one or more organic solvents,
5 to 10 wt. % of one or more organic polymers, and
0 to 5 wt. % of one or more organic additives.

The aluminum pastes of the present invention are viscous compositions, which may be prepared by mechanically mixing the particulate aluminum, the tin-organic component, the optional zinc-organic component, the optional glass frit composition(s) and the optional amorphous silicon dioxide with the organic vehicle. In an embodiment, the manufacturing method power mixing, a dispersion technique that is equivalent to the traditional roll milling, may be used; roll milling or other mixing technique can also be used.

The aluminum pastes of the present invention can be used as such or may be diluted, for example, by the addition of additional organic solvent(s); accordingly, the weight percentage of all the other constituents of the aluminum paste may be decreased.

The aluminum pastes of the present invention may be used in the manufacture of aluminum back electrodes of silicon solar cells or respectively in the manufacture of silicon solar cells. The manufacture may be performed by applying the aluminum pastes to the back-side of silicon wafers, i.e., to those surface portions thereof which are or will not be covered by other back-side metal pastes like, in particular, back-side silver or silver/aluminum pastes. The silicon wafers may comprise monocrystalline or polycrystalline silicon. In an embodiment, the silicon wafers may have an area of 100 to 250 cm² and a thickness of 180 to 300 μm. However, the aluminum pastes of the present invention can be successfully used even for the production of aluminum back electrodes on the back-side of silicon wafers that are larger and/or having a lower thickness, for example, silicon wafers having a thickness below 180 μm, in particular in the range of 140 to below 180 μm and/or an area in the range of above 250 to 400 cm².

The aluminum pastes are applied to a dry film thickness of, for example, 15 to 60 μm. The method of aluminum paste application may be printing, for example, silicone pad printing or, in an embodiment, screen printing. The application viscosity of the aluminum pastes of the present invention may be 20 to 200 Pa·s when it is measured at a spindle speed of 10 rpm and 25° C. by a utility cup using a Brookfield HBT viscometer and #14 spindle.

After application of the aluminum pastes to the back-side of the silicon wafers they may be dried, for example, for a period of 1 to 100 minutes with the wafers reaching a peak temperature in the range of 100 to 300° C. Drying can be carried out making use of, for example, belt, rotary or stationary driers, in particular, IR (infrared) belt driers.

After their application or, in an embodiment, after their application and drying, the aluminum pastes of the present invention are fired to form aluminum back electrodes. Firing may be performed, for example, for a period of 1 to 5 minutes with the silicon wafers reaching a peak temperature in the range of 700 to 900° C. Firing can be carried out making use of, for example, single or multi-zone belt furnaces, in particular, multi-zone IR belt furnaces. Firing happens in the presence of oxygen, in particular, in the presence of air. During firing the organic substance including non-volatile organic material and the organic portion not evaporated during the possible drying step may be removed, i.e. burned and/or carbonized, in particular, burned. The organic substance removed during firing includes organic solvent(s), possible organic polymer(s), possible organic additive(s), the organic moieties of the one or more tin-organic compounds and of the possible one or more zinc-organic compounds. The tin may remain as tin oxide after firing. In an embodiment, the tin oxide after firing may be SnO, SnO₂, or a mixture thereof, for example. In case the aluminum pastes comprise zinc-organic compounds the zinc may remain as zinc oxide after firing. In case the aluminum pastes comprise glass frit(s), there may be a further process taking place during firing, namely sintering of the glass frit(s). Firing may be performed as so-called cofiring together with further metal pastes that have been applied to the silicon wafer, i.e., front-side and/or back-side metal pastes which have been applied to form front-side and/or back-side electrodes on the wafer's surfaces during the firing process. An embodiment includes front-side silver pastes and back-side silver or back-side silver/aluminum pastes.

Next, a non-limiting example in which a silicon solar cell is prepared using an aluminum paste of the present invention is explained, referring to FIG. 2.

First, a silicon wafer substrate 102 is prepared. On the light-receiving side face (front-side surface) of the silicon wafer, normally with the p-n junction close to the surface, front-side electrodes (for example, electrodes mainly composed of silver) 104 are installed (FIG. 2A). On the back-side of the silicon wafer, a silver or silver/aluminum electroconductive paste (for example, PV202 or PV502 or PV583 or PV581, commercially available from E.I. Du Pont de Nemours and Company) is spread to form either busbars or tabs to enable interconnection with other solar cells set in parallel electrical configuration. On the back-side of the silicon wafer, a novel aluminum paste of the present invention used as a back-side (or p-type contact) electrode for a solar cell, 106 is spread by screen printing using the pattern that enable slight overlap with the silver or silver/aluminum paste referred to above, etc., then dried (FIG. 2B). Drying of the pastes is performed, for example, in an IR belt drier for a period of 1 to 10 minutes with the wafer reaching a peak temperature of 100 to 300° C. Also, the aluminum paste may have a dried film thickness of 15 to 60 μm, and the thickness of the silver or silver/aluminum paste may be 15 to 30 μm. Also, the overlapped part of the aluminum paste and the silver or silver/aluminum paste may be about 0.5 to 2.5 mm.

Next, the substrate obtained is fired, for example, in a belt furnace for a period of 1 to 5 minutes with the wafer reaching a peak temperature of 700 to 900° C., so that the desired silicon solar cell is obtained (FIG. 2D). An electrode 110 is formed from the aluminum paste wherein said paste has been fired to remove the organic substance and, in case the aluminum paste comprises glass frit, to sinter the latter.

The silicon solar cell obtained using the aluminum paste of the present invention, as shown in FIG. 2D, has electrodes 104 on the light-receiving face (surface) of the silicon substrate 102, aluminum electrodes 110 mainly composed of aluminum and silver or silver/aluminum electrodes 112 mainly composed of silver or silver and aluminum (formed by firing silver or silver/aluminum paste 108), on the back-side.

### EXAMPLES

The examples cited here relate to thick-film metallization pastes fired onto conventional solar cells that have a silicon nitride anti-reflection coating and front side n-type contact thick film silver conductor.

The present invention can be applied to a broad range of semiconductor devices, although it is especially effective in light-receiving elements such as photodiodes and solar cells. The discussion below describes how a solar cell is formed utilizing the composition(s) of the present invention and how it is tested for its technological properties.

### (1) Manufacture of Solar Cell

A solar cell was formed as follows:
(i) On the back face of a Si substrate (200 μm thick multicrystalline silicon wafer of area 243 cm², p-type (boron) bulk silicon, with an n-type diffused POCl₃ emitter, surface texturized with acid, SiNₓ anti-reflective coating (ARC) on the wafer's emitter applied by CVD) having a 20 μm thick silver electrode on the front surface (PV145 Ag composition commercially available from E. I. Du Pont de Nemours and Company) an Ag/Al paste (PV202, an Ag/Al composition commercially available from E. I. Du Pont de Nemours and Company) was printed and dried as 5 mm wide bus bars. Then, an aluminum paste for the back face electrode of a solar cell was screen-printed at a dried film thickness of 30 μm providing overlap of the aluminum film with the Ag/Al busbar for 1 mm at both edges to ensure electrical continuity. The screen-printed aluminum paste was dried before firing.

The example aluminum pastes comprised 72 wt. % air-atomized aluminium powder (average particle size 6 μm), 26 wt. % organic vehicle of polymeric resins and organic solvents and 0.07 wt. % amorphous silica. The example aluminum pastes C to F (according to the invention) comprised tin(II) 2-ethylhexanoate additions in the range of 0.1 to 0.5 wt. %, whereas the control example aluminum pastes A and B (comparative examples) comprised no addition of tin-organic compounds. Control example aluminum paste A comprised no zinc-organic compounds, whereas control example aluminum paste B and the example aluminum pastes C to F comprised 1.0 wt. % zinc neodecanoate.
(ii) The printed wafers were then fired in a Centrotherm furnace at a belt speed of 3000 mm/min with zone temperatures defined as zone 1=450° C., zone 2=520° C., zone 3=570° C. and the final zone set at 950° C., thus the wafers reaching a peak temperature of 850° C. After firing, the metallized wafer became a functional photovoltaic device.

Measurement of the electrical performance, fired adhesion and bowing was undertaken.

### (2) Test Procedures

### Efficiency

The solar cells formed according to the method described above were placed in a commercial I-V tester (supplied by EETS Ltd.) for the purpose of measuring light conversion efficiencies. The lamp in the I-V tester simulated sunlight of a known intensity (approximately 1000 W/m²) and illuminated the emitter of the cell. The metallizations printed onto the fired cells were subsequently contacted by four electrical probes. The photocurrent (Voc, open circuit voltage; Isc, short circuit current) generated by the solar cells was measured over arrange of resistances to calculate the I-V response curve. Fill Factor (FF) and Efficiency (Eff) values were subsequently derived from the I-V response curve.

### Fired Adhesion

In order to measure the cohesive strength of the Al metallizations the amount of material removed from the surface of the fired wafer was determined using a peel test. To this end a transparent layer of adhesive tape was applied and subsequently peeled off. The adhesion figures in Table 1 illustrate an increase in the paste's adhesion as with a corresponding increase in the tin-organic content of the composition. Peel strength of the example pastes could be further enhanced with the addition of glass frit.

### Bowing Measurement

Bowing (cell warpage) is defined as the maximum deflection height of the centre of the fired cell at room temperature when measured upon a flat surface. Bowing measurements were performed by placing the cells on a metal flat-bed and using a dial gauge with μm resolution to measure the maximum deflection of each cell, i.e. determining the distance of the centre of the wafer from the flat bed surface.

Examples C to F cited in Table 1 illustrate the electrical properties of the aluminum pastes as a function of tin-organic content in comparison to the compositions without the tin-organic additive (control A and B). The data in Table 1 confirms that the bowing is decreased with a further enhancement of adhesion for Examples C to F.

TABLE 1

| | wt. % | | | | | | | |
|---|---|---|---|---|---|---|---|---|
| | Sn- | wt. % | Voc | | | | Bowing | Adhesion |
| Example | organic | glass frit | (mV) | Isc (A) | Eff (%) | FF (%) | (μm) | (%) |
| Control A | 0.0 | 0.0 | 603.0 | 8.405 | 14.70 | 70.7 | 1242 | 15 |
| Control B | 0.0 | 0.0 | 603.6 | 8.321 | 14.95 | 73.0 | 1507 | 60 |
| C | 0.1 | 0.0 | 603.1 | 8.323 | 14.85 | 72.0 | 1123 | 80 |
| D | 0.2 | 0.0 | 604.7 | 8.243 | 14.97 | 72.4 | 814 | 85 |
| E | 0.5 | 0.0 | 605.6 | 8.371 | 15.30 | 73.6 | 520 | 90 |
| F | 0.5 | 0.5 | 605.3 | 8.298 | 15.15 | 73.4 | 601 | 98 |

What is claimed is:

1. Aluminum paste comprising particulate aluminum, a tin-organic component and an organic vehicle comprising organic solvent(s).

2. The aluminum paste of claim 1 additionally comprising one or more glass frits in a total proportion of 0.01 to 5 wt. %, based on total aluminum paste composition.

3. The aluminum paste of claim 1 additionally comprising a zinc-organic component in a proportion corresponding to a zinc contribution of 0.05 to 0.6 wt. %, based on total aluminum paste composition.

4. The aluminum paste of claim 1 additionally comprising amorphous silicon dioxide in a proportion of above 0 to 0.5 wt. %, based on total aluminum paste composition.

5. The aluminum paste of claim 1, wherein the particulate aluminum is present in a proportion of 50 to 80 wt. %, based on total aluminum paste composition.

6. The aluminum paste of claim 1, wherein the tin-organic component is selected from the group consisting of one solid tin-organic compound, a combination of two or more solid tin-organic compounds, one liquid tin-organic compound, a combination of two or more liquid tin-organic compounds, a combination of solid and liquid tin-organic compounds and a solution of one or more tin-organic compounds in organic solvent(s).

7. The aluminum paste of claim 6, wherein the tin-organic component is present in a proportion corresponding to a tin contribution of 0.01 to 0.5 wt. %, based on total aluminum paste composition.

8. The aluminum paste of claim 6, wherein the tin-organic compound(s) is/are tin-organic salt compounds selected from the group consisting of tin resinates and tin carboxylates.

9. The aluminum paste of claim 6, wherein the tin-organic component is tin(II) 2-ethylhexanoate being present in a proportion of 0.1 to 1 wt. %, based on total aluminum paste composition.

10. The aluminum paste of claim 1, wherein the organic vehicle further comprises organic polymer(s) and/or organic additive(s).

11. A process of forming a silicon solar cell comprising the steps:
(i) applying an aluminum paste of claim 1 on the back-side of a silicon wafer having a p-type region, an n-type region and a p-n junction, and
(ii) firing the surface provided with the aluminum paste, whereby the wafer reaches a peak temperature of 700 to 900° C.

12. The process of claim 11, wherein the application of the aluminum paste is performed by printing.

13. The process of claim 11, wherein firing is performed as cofiring together with other front-side and/or back-side metal pastes that have been applied to the silicon wafer to form front-side and/or back-side electrodes thereon during firing.

14. Silicon solar cells made by the process of claim 11.

15. A silicon solar cell comprising an aluminum back electrode wherein the aluminum back electrode is produced making use of an aluminum paste of claim 1.

16. The silicon solar cell of claim 15, further comprising a silicon wafer.
